(19) United States
(12) Patent Application Publication
(10) Pub. No.: US 2021/0328146 A1
(43) Pub. Date: Oct. 21, 2021

(54) APPARATUS AND VACUUM SYSTEM FOR CARRIER ALIGNMENT IN A VACUUM CHAMBER, AND METHOD OF ALIGNING A CARRIER

(71) Applicant: Applied Materials, Inc., Santa Clara, CA (US)

(72) Inventors: Matthias HEYMANNS, Münster (DE); Tommaso VERCESI, Aschaffenburg (DE); Stefan BANGERT, Steinau (DE); Ulrich OLDENDORF, Ober-Ramstadt (DE); Achim HUWIG, Dreieich (DE)

(21) Appl. No.: 16/335,231

(22) PCT Filed: Apr. 3, 2018
(86) PCT No.: PCT/EP2018/058470

§ 371 Date: Mar. 20, 2019

(51) Int. Cl. H01L 51/00; C23C 14/24; C23C 14/56; C23C 14/04; H01L 51/56

(52) U.S. Cl. CPC H01L 51/0012; C23C 14/24; C23C 14/564; H01L 51/56; H01L 51/001; H01L 51/0011; C23C 14/042

(57) ABSTRACT

An apparatus for carrier alignment in a vacuum chamber is described. The apparatus includes a support extending in a first direction in the vacuum chamber, a magnetic levitation system configured to transport a first carrier in the first direction in the vacuum chamber, the magnetic levitation system comprising at least one magnet unit, and an alignment system for aligning the first carrier. The at least one magnet unit and the alignment system are rigidly fixed to the support. Further, a vacuum system and a method of aligning a carrier are described.

### FIELD

Embodiments of the present disclosure relate to an apparatus and a vacuum system for aligning a carrier in a vacuum chamber, and to a method of aligning a carrier in a vacuum chamber. More specifically, a method of transporting, positioning, and aligning a substrate carrier carrying a substrate in a vacuum chamber is described. Embodiments of the present disclosure particularly relate to a vacuum deposition system for depositing a material on a substrate carried by a carrier, wherein the substrate is aligned with respect to a mask before the deposition. Methods and apparatuses described herein may be used in the manufacture of organic light-emitting diode (OLED) devices.

### BACKGROUND

Techniques for layer deposition on a substrate include, for example, thermal evaporation, physical vapor deposition (PVD), and chemical vapor deposition (CVD). Coated substrates may be used in several applications and in several technical fields. For instance, coated substrates may be used in the field of organic light emitting diode (OLED) devices. OLEDs can be used for the manufacture of television screens, computer monitors, mobile phones, other hand-held devices and the like, e.g. for displaying information. An OLED device, such as an OLED display, may include one or more layers of an organic material situated between two electrodes that are all deposited on a substrate.

During the deposition of a coating material on a substrate, the substrate may be held by a substrate carrier, and a mask may be held by a mask carrier in front of the substrate. A material pattern, e.g. a plurality of pixels, corresponding to an opening pattern of the mask can be deposited on the substrate, e.g. by evaporation.

The functionality of an OLED device typically depends on the accuracy of the coating pattern and the thickness of the organic material, which have to be within a predetermined range. For obtaining high-resolution OLED devices, technical challenges with respect to the deposition of evaporated materials need to be mastered. In particular, an accurate and smooth transport of a substrate carrier carrying a substrate and/or of a mask carrier carrying a mask through a vacuum system is challenging. Further, a precise alignment of the substrate with respect to the mask is crucial for achieving high quality deposition results, e.g. for producing high-resolution OLED devices. Yet further, an efficient utilization of the coating material is beneficial, and idle times of the system are to be kept as short as possible.

In view of the above, it would be beneficial to provide apparatuses, systems and methods for accurately and reliably transporting, positioning and/or aligning carriers for carrying substrates and/or masks in a vacuum chamber.

### SUMMARY

In light of the above, an apparatus and a vacuum system for carrier alignment in a vacuum chamber, and a method of aligning a carrier in a vacuum chamber are provided. Further aspects, benefits, and features of the present disclosure are apparent from the claims, the description, and the accompanying drawings.

According to an aspect of the present disclosure, an apparatus for carrier alignment in a vacuum chamber is provided. The apparatus includes a support extending in a first direction in the vacuum chamber, a magnetic levitation system configured to transport a first carrier in the first direction, wherein the magnetic levitation system includes at least one magnet unit, and an alignment system for aligning the first carrier. The at least one magnet unit and the alignment system are fixed to the support.

In some embodiments, the first carrier is a substrate carrier configured to carry a substrate. In some embodiments, the alignment system is configured to align a first carrier, e.g. a substrate carrier, with respect to a second carrier, e.g. a mask carrier, for depositing a material on a substrate that is carried by the first carrier.

According to another aspect of the present disclosure, a vacuum system for carrier alignment in a vacuum chamber is provided. The vacuum system includes a vacuum chamber with a top wall and a side wall, a support provided in the vacuum chamber at the top wall, and an alignment system for aligning a first carrier, the alignment system being fixed to the support, wherein the alignment system extends through the side wall and is flexibly connected to the side wall, particularly via a vibration damping element or a vibration isolation element.

In some embodiments, the vacuum system is a vacuum deposition system including a deposition source for depositing a material on a substrate carried by the first carrier in the vacuum chamber.

According to a further aspect of the present disclosure, an apparatus for carrier alignment in a vacuum chamber is provided. The apparatus includes a support extending in a first direction in the vacuum chamber, a (first) magnetic levitation system configured to transport a first carrier in the first direction in the vacuum chamber, the (first) magnetic levitation system comprising at least one magnet unit, and a second magnetic levitation system configured to transport a second carrier in the first direction parallel to the first carrier, the second magnetic levitation system including at least one second magnet unit. The at least one magnet unit and the at least one second magnet unit are fixed to the support. The apparatus may optionally further include an alignment system as described herein.

According to a further aspect of the present disclosure, a method of aligning a carrier in a vacuum chamber is provided. The method includes contactlessly transporting a first carrier in a first direction along a support with a magnetic levitation system, the support extending in the first direction and having at least one magnet unit of the magnetic levitation system attached thereto, and aligning the first carrier in a second direction transverse to the first direction, and optionally in the first direction and/or in a third direction transverse to the first and second directions, with an alignment system that is fixed to the support.

In some embodiments, the first carrier is a substrate carrier which holds a substrate, and aligning the first carrier includes aligning the substrate carrier with respect to a second carrier which holds a mask.

In some embodiments, the alignment system extends through a side wall of the vacuum chamber, and is flexibly connected to the side wall, particularly via at least one vibration damping element such as a flexible and/or elastic sealing or a bellow element. Accordingly, vibrations or other deformations of the side wall are not transferred from the side wall to the alignment system or are transferred to the alignment system to a reduced extent. The alignment accuracy can be improved.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic sectional view of an apparatus for aligning a carrier according to embodiments described herein;

FIG. 2 shows a schematic sectional view of an apparatus for aligning a carrier according to embodiments described herein;

FIG. 3 shows a schematic sectional view of an apparatus for aligning a carrier according to embodiments described herein in a first position;

FIG. 4A shows the apparatus of FIG. 3 in a second position;

FIG. 4B shows the apparatus of FIG. 3 in a third position;

FIG. 5 shows a schematic sectional view of an apparatus for aligning a carrier according to embodiments described herein;

FIG. 6 shows an exploded view of the alignment system of the apparatus of FIG. 5;

FIG. 7 shows a perspective view of the alignment system of the apparatus of FIG. 5;

FIG. 8 is a flow diagram illustrating a method of aligning a carrier in a vacuum chamber according to embodiments described herein; and

FIG. 9 shows a schematic sectional view of an apparatus for aligning a carrier according to embodiments described herein.

### DETAILED DESCRIPTION OF EMBODIMENTS

Reference will now be made in detail to the various embodiments of the disclosure, one or more examples of which are illustrated in the figures. Within the following description of the drawings, same reference numbers refer to same components. Generally, only the differences with respect to individual embodiments are described. Each example is provided by way of explanation of the disclosure and is not meant as a limitation of the disclosure.

Further, features illustrated or described as part of one embodiment can be used on or in conjunction with other embodiments to yield yet a further embodiment. It is intended that the description includes such modifications and variations.

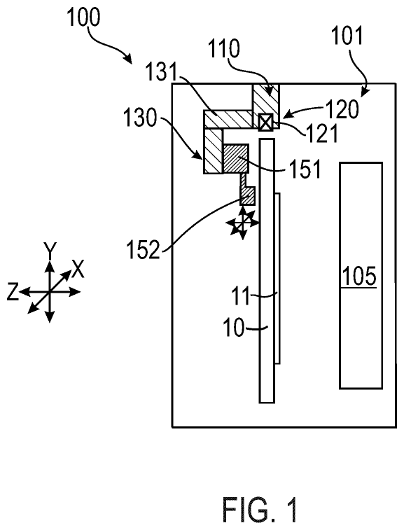

FIG. 1 is a schematic sectional view of an apparatus 100 for aligning a first carrier 10 in a vacuum chamber 101 according to embodiments described herein. The term “aligning” refers to a positioning of the first carrier exactly at a predetermined position in the vacuum chamber, particularly at a predetermined position relative to a second carrier. The first carrier is aligned in at least one alignment direction, particularly in two or three alignment directions which may be essentially perpendicular with respect to each other.

In the following description, the term “first carrier” is used to designate a substrate carrier which is configured to carry a substrate 11, as is schematically depicted in FIG. 1. The term “second carrier” is used to designate a mask carrier which is configured to carry a mask (see FIG. 3). However, it is to be understood that, alternatively, the first carrier may be a carrier configured to hold a different object, e.g. a mask or a shield.

A “substrate carrier” relates to a carrier device configured to carry a substrate 11 along a first transport path in the vacuum chamber 101. The substrate carrier may hold the substrate 11 during the deposition of a coating material on the substrate 11. In some embodiments, the substrate 11 may be held at the substrate carrier in a non-horizontal orientation, particularly in an essentially vertical orientation, e.g. during transport, alignment and/or deposition. In the embodiment depicted in FIG. 1, the substrate 11 is held at the first carrier 10 in an essentially vertical orientation. For example, an angle between the substrate surface and the gravity vector may be less than 10°, particularly less than 5°.

For example, the substrate 11 may be held at the first carrier 10 by a chucking device, e.g. by an electrostatic chuck (ESC) or by a magnetic chuck. The chucking device may be integrated in the first carrier 10, e.g. in an atmospheric enclosure provided in the first carrier.

The first carrier 10 may include a carrier body with a holding surface configured to hold the substrate 11, particularly in a non-horizontal orientation, more particularly in an essentially vertical orientation. The first carrier may be movable along the first transport path by a carrier transport system which comprises a magnetic levitation system 120. The first carrier 10 may be contactlessly held during the transport by the magnetic levitation system 120. In particular, the magnetic levitation system 120 may be configured to contactlessly transport the first carrier 10 along the first transport path in the vacuum chamber. The magnetic levitation system 120 may be configured to transport the first carrier from a loading chamber into a deposition area of the vacuum chamber 101 where an alignment system and a deposition source are arranged.

A “mask carrier” as used herein relates to a carrier device configured to carry a mask for the transport of the mask along a mask transport path in the vacuum chamber. The mask carrier may carry the mask during transport, during alignment and/or during deposition on the substrate through the mask. In some embodiments, the mask may be held at the mask carrier in a non-horizontal orientation, particularly in an essentially vertical orientation during transport and/or alignment. The mask may be held at the mask carrier by a chucking device, e.g. a mechanic chuck such as a clamp, an electrostatic chuck or a magnetic chuck. Other types of chucking devices may be used which may be connected to or integrated in the mask carrier.

For instance, the mask may be an edge exclusion mask or a shadow mask. An edge exclusion mask is a mask which is configured for masking one or more edge regions of the substrate, such that no material is deposited on the one or more edge regions during the coating of the substrate. A shadow mask is a mask configured for masking a plurality of features which are to be deposited on the substrate. For instance, the shadow mask can include a plurality of small openings, e.g. an opening pattern with 10.000 or more openings, particularly 1.000.000 or more openings. A pattern of pixels can be deposited on the substrate through the mask, e.g. for the manufacture of a display such as an OLED display.

An “essentially vertical orientation” as used herein may be understood as an orientation with a deviation of 10° or less, particularly 5° or less from a vertical orientation, i.e. from the gravity vector. For example, an angle between a main surface of a substrate (or mask) and the gravity vector may be between +10° and −10°, particularly between 0° and −5°. In some embodiments, the orientation of the substrate (or mask) may not be exactly vertical during transport and/or during deposition, but slightly inclined with respect to the vertical axis, e.g. by an inclination angle between 0° and −5°, particularly between −1° and −5°. A negative angle refers to an orientation of the substrate (or mask) wherein the substrate (or mask) is inclined downward.

The apparatus 100 according to embodiments described herein includes a magnetic levitation system 120 that is configured to contactlessly transport the first carrier 10 in the first direction X. The first direction X may be an essentially horizontal direction.

The first direction X is perpendicular to the paper plane of FIG. 1.

A support 110 is provided in the vacuum chamber 101 and extends in the first direction X. At least one magnet unit 121 of the magnetic levitation system is provided at the support 110. In particular, the magnetic levitation system includes a plurality of magnet units which are provided at the support 110. The plurality of magnet units may be arranged at the support 110 at predetermined distances from each other in the first direction X, such that the carrier can be held by at least two magnet units at a time when being transported along the support 110 in the first direction X. Accordingly, the support 110 may provide a guiding track or guiding rail along which the first carrier can be contactlessly transported.

The at least one magnet unit 121 may be configured to generate a magnetic levitation force for holding the first carrier 10 contactlessly with respect to the support 110. The at least one magnet unit 121 may be an actively controlled magnet unit configured to hold the carrier at the support 110 at a predetermined distance below the at least one magnet unit 121 by magnetic forces. In some embodiments, the at least one magnet unit 121 includes an actuator that is arranged at the support 110, particularly above the first carrier 10. The actuator may be actively controllable for maintaining a predetermined distance between the support 110 and the first carrier 10 that is held by the actuator. A magnetic counterpart may be arranged at the first carrier which can interact with the magnet units provided at the support 110.

For example, an output parameter such as an electric current which is applied to the at least one magnet unit 121 may be controlled depending on an input parameter such as a distance between the first carrier and the support. In particular, a distance between the support 110 and the first carrier 10 may be measured by a distance sensor, and the magnetic field strength of the at least one magnet unit 121 may be set depending on the measured distance. In particular, the magnetic field strength may be increased in the case of a distance above a predetermined threshold value, and the magnetic field strength may be decreased in the case of a distance below the threshold value. The at least one magnet unit 121 may be controlled in a closed loop or feedback control. Two or more magnet units may be actively controlled, wherein each of the two or more magnet units carries a part of the weight of the first carrier. Thus, the first carrier can be held below the two or more magnet units.

The support 110 may have a dimension of several meters in the first direction X, e.g. a dimension of 1 m or more, 2 m or more, or 3 m or more. The first carrier can be transported along the support 110 in the extension direction of the support. At least a portion of the support 110 may be configured as a guiding rail for guiding the first carrier along the support. A plurality of actively controlled magnet units may be provided at the guiding rail portion of the support.

In some embodiments, the support 110 is provided at a top wall of the vacuum chamber 101, e.g. mechanically fixed to the top wall of the vacuum chamber. The first carrier 10 can be contactlessly transported below a guiding rail portion of the support in the first direction X via a plurality of actively controlled magnet units.

The apparatus 100 further includes an alignment system 130 configured to align the first carrier 10 in the vacuum chamber 101, as is schematically depicted in FIG. 1. The alignment system 130 may be configured to accurately position the first carrier 10 in the vacuum chamber. In some embodiments, a deposition source 105 is provided in the vacuum chamber 101. The deposition source 105 is configured for depositing a coating material on the substrate 11 that is held by the first carrier 10. The alignment system 130 may be arranged in a deposition area of the vacuum chamber. Accordingly, a material can be deposited on a substrate that is carried by the first carrier after the alignment.

In some embodiments, which may be combined with other embodiments described herein, the alignment system 130 includes a first mount 152 for mounting the first carrier 10 to the alignment system, and an alignment device 151 configured to move the first mount 152 in at least one alignment direction. The at least one alignment direction may be a second direction Z which extends transverse to the first direction X. In some embodiments, the at least one alignment direction may be the first direction X, the second direction Z, and/or the third direction Y which extends transverse to the first and second directions. In some embodiments, the alignment device may be configured to move the first mount in the first direction X and in the third direction Y. In some embodiments, the alignment device 151 is configured to move the first mount 152 in the second direction Z, and optionally in at least one of the first direction X and the third direction Y perpendicular to the first and second directions. The third direction Y may be an essentially vertical direction.

The second direction Z may be an essentially horizontal direction. The second direction Z may be essentially perpendicular to the first direction X along which the first carrier is transported by the magnetic levitation system 120. After the transport of the first carrier in the first direction X, the first carrier can be mounted to the first mount 152 and be shifted in the second direction Z away from the first transport path by the alignment system 130, e.g. toward the deposition source 105 or toward a second carrier carrying a mask.

According to an aspect described herein, both the at least one magnet unit 121 of the magnetic levitation system 120 and the alignment system 130 are fixed to the support 110. In particular, a plurality of levitation magnets of the magnetic levitation system 120 and the alignment system 130 are fixed to the support 110.

By fixing the at least one magnet unit 121 and the alignment system 130 to the same mechanical support, vibrations and other movements such as deformations of the vacuum chamber are equally transferred both to the at least one magnet unit 121 and to the alignment system 130. In particular, the at least one magnet unit 121 and the alignment system 130 may be connected to the vacuum chamber 101 via the same mechanical path, i.e. through the support 110. Thus, movements and vibrations of different parts of the vacuum chamber do not affect the relative positioning between the at least one magnet unit 121 and the alignment system 130. For example, the evacuation of the vacuum chamber may have a different effect on the side wall and on the top wall of the vacuum chamber which may move differently. However, since both the at least one magnet unit 121 and the alignment system 130 are connected to the top wall of the vacuum chamber via the same mechanical support, these different movements do not affect the relative positioning between the at least one magnet unit 121 and the alignment system 130. Further, since the magnet units and the alignment system are connected to the vacuum chamber via the same mechanical path provided by the common support, the tolerance chain for the alignment of the carriers can be reduced. In particular, the alignment device (i.e. the piezo actuator), the shifting devices (i.e. the linear Z-actuators) and the maglev units (i.e. the magnet units) may be connected to the same mechanical support. The alignment accuracy can be improved.

According to embodiments described herein, the first mount 152 of the alignment system 130 attaches to a predetermined section of the first carrier 10 when the first carrier has been transported into the deposition area by the magnetic levitation system 120. Accordingly, the alignment to be performed by the alignment system 130 is more reliable and reproducible, and similar or essentially equal strokes of the alignment system 130 can be used for the carrier alignment of subsequent carrier, even if the vacuum chamber vibrates or moves. The alignment can be improved and the deposition can be carried out more accurately and in a time-efficient way.

As is schematically depicted in FIG. 1, an alignment device 151 of the alignment system 130 may be mechanically fixed to the support 110 via a main body 131 of the alignment system 130.

According to embodiments, which may be combined with other embodiments described herein, the alignment system 130 includes a first mount 152 and an alignment device 151 configured to move the first mount 152 in at least one alignment direction. The alignment device 151 may include at least one precision actuator, e.g. at least one piezo actuator, configured to move the first mount 152 in the at least one alignment direction. In particular, the alignment device 151 includes two or three piezo actuators configured to move the first mount in two or three alignment directions. The piezo actuator of the alignment device 151 may be configured to move the first mount 152 in the second direction Z, and optionally in the first direction X and/or in the third direction Y. The alignment device 151 may be configured for a fine positioning (or fine alignment) of the first mount 152 having the first carrier mounted thereon in the at least one alignment direction. For example, the alignment device may be configured for a positioning of the first carrier with a sub-5-μm accuracy, particularly with a sub-μm accuracy.

In some embodiments, which may be combined with other embodiments described herein, the first mount 152 includes a magnetic chuck configured to magnetically hold the first carrier 10 at the first mount 152. For example, the first mount 152 may include an electropermanent magnet device configured to magnetically hold the first carrier at the first mount. An electropermanent magnet device can be switched between a holding state and a releasing state by applying an electric pulse to a coil of the electropermanent magnet device. In particular, a magnetization of at least one magnet of the electropermanent magnet device can be changed by applying the electric pulse.

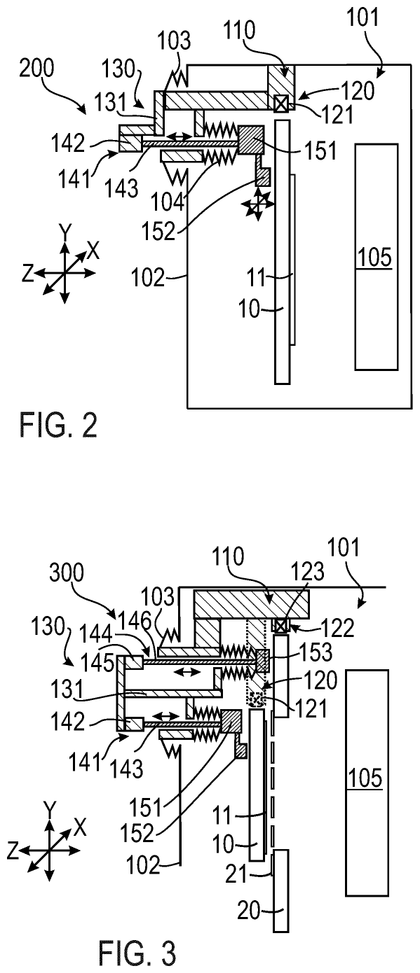

FIG. 2 shows an apparatus 200 for carrier alignment in a vacuum chamber 101 according to some embodiments described herein in a schematic sectional view. The apparatus 200 is similar to the apparatus 100 shown in FIG. 1, such that reference can be made to the above explanations, which are not repeated here.

The apparatus 200 includes a magnetic levitation system 120 configured to transport the first carrier 10 in the first direction X. The magnetic levitation system 120 includes at least one magnet unit 121, particularly at least one actively controlled magnet unit configured to contactlessly hold the first carrier 10 with respect to the support 110. The at least one magnet unit 121 and the alignment system 130 are fixed to the support 110, as was described above with reference to FIG. 1.

The alignment system 130 includes a first mount 152 configured to mount the first carrier 10 to the alignment system 130, and a first shifting device 141 configured to move the first mount in the second direction Z, particularly essentially perpendicular to the first direction X. In some embodiments, the alignment system 130 further includes an alignment device 151 configured to move the first mount 152 in at least one alignment direction, wherein the first shifting device 141 may be configured to move the alignment device 151 together with the first mount 152 in the second direction Z. The alignment device 151 may optionally include one or more piezo actuators.

Accordingly, the first mount 152 can be moved by the first shifting device 141 in the second direction Z, e.g. for performing a coarse positioning of the first carrier that is mounted to the first mount, and the first mount 152 can additionally be moved by the alignment device 151, e.g. for performing a fine positioning of the first carrier that is mounted to the first mount.

In some embodiments, the at least one alignment direction may essentially correspond to the second direction Z. Accordingly, the first carrier can be moved in the second direction Z by the first shifting device 141 and by the alignment device 151. The first shifting device 141 may be configured to perform a coarse positioning of the first carrier in the second direction Z, and the alignment device 151 may be configured to perform a fine alignment of the first carrier in the second direction Z.

In some embodiments, the alignment device 151 is configured to move the first mount 152 in the second direction Z, and optionally in at least one of the first direction X and a third direction Y transverse to the first and second direction. The third direction Y may be an essentially vertical direction. Accordingly, the first carrier can be exactly positioned by the alignment device 151 in the first direction X, the second direction Z and/or the third direction Y. In other embodiments, the alignment device 151 can move the first mount only in two directions, e.g. in the second direction Z and in the third direction Y.

In some embodiments, which may be combined with other embodiments described herein, the first shifting device 141 includes a driving unit 142 and a driven part 143 which can be moved by the driving unit 142 in the second direction Z. The driving unit 142 may be rigidly fixed to the main body 131 of the alignment system 130 which is rigidly fixed to the support 110. The first mount 152 and optionally the alignment device 151 may be provided at the driven part 143 of the first shifting device 141 to be movable together with the driven part 143 in the second direction Z. In particular, the driven part 143 may comprise a linearly extending shaft extending from outside the vacuum chamber into the vacuum chamber in the second direction Z and can be moved by the driving unit 142.

In some embodiments, the driving unit 142 of the first shifting device 141 may include a linear actuator configured to move the driven part 143 in the second direction Z by a distance of 10 mm or more, particularly 20 mm or more, more particularly 30 mm or more. For example, the driving unit 142 may include a mechanical actuator, an electro-mechanical actuator, e.g. a stepper motor, an electric motor, a hydraulic actuator and/or a pneumatic actuator configured to move the driven part 143 in the second direction Z by a distance of 10 mm or more.

A method of aligning the first carrier 10 in the vacuum chamber may include the following: (i) Transporting the first carrier 10 along a first transport path in a first direction X into a deposition area of the vacuum chamber 101. The first carrier 10 is contactlessly transported by the magnetic levitation system 120 having at least one magnet unit 121. The at least one magnet unit 121 may be an actively controlled magnet unit fixed to a support 110 and configured to contactlessly hold the first carrier 10 at the support 110. (ii) Mounting the first carrier to a first mount 152 of an alignment system 130 in the deposition area. The alignment system 130 is fixed to the support 110 and includes an alignment device 151 configured to move the first mount 152 in at least one alignment direction. The alignment system 130 may further include a first shifting device 141 configured to move the alignment device together with the first mount in the second direction Z. Mounting the first carrier to the first mount 152 may include moving the first mount 152 toward the first carrier 10 that is positioned on the first transport path until the first mount 152 contacts the first carrier and attaches to the first carrier. For example, the first mount 152 magnetically attached to the first carrier.

(iii) Optionally, the method may further include moving the first carrier in the second direction Z with the first shifting device 141. For example, the first shifting device 141 may move the first carrier 10 in the second direction Z by a distance of 10 mm or more toward a deposition source 105 or toward a second carrier. (iv) The first carrier is aligned in at least one alignment direction with the alignment device 151. Aligning the first carrier 10 may include a fine positioning of the first carrier 10 in the second direction Z, and optionally in at least one of the first direction X and the third direction Y. The first carrier may be aligned by at least one piezo actuator which is provided at the driven part 143 of the first shifting device 141 inside the vacuum chamber 101. Accordingly, an accurate alignment of the first carrier 10 can be provided with the apparatus 100 described herein.

In particular, by having the alignment device 151 together with the first mount 152 provided at the driven part 143 of the first shifting device 141, a coarse positioning of the first mount can be performed by the first shifting device 141, and a fine positioning of the first mount can be provided by the alignment device 151.

In some embodiments, which can be combined with other embodiments described herein, the driving unit 142 of the first shifting device 141 is arranged outside the vacuum chamber 101, and/or the driven part 143 extends into the vacuum chamber 101, particularly through an opening in a side wall 102 of the vacuum chamber 101.

When the driving unit 142 is arranged outside the vacuum chamber, i.e. under atmospheric pressure, a non-vacuum compatible driving unit can be used which is typically more cost-efficient and easier to handle than a vacuum-compatible driving unit. Further, an arbitrary type of driving unit 142, e.g. including an electric motor or a stepper motor can be provided. The generation of particles inside the vacuum chamber by the driving unit which may include mechanical bearings can be avoided. For example, a linear Z-actuator can be used. Maintenance of the driving unit can be facilitated.

In some embodiments, which may be combined with other embodiments described herein, the apparatus 200 comprises a vibration damping element 103 for providing a vibration damping or a vibration isolation between the alignment system 130 and a wall, particularly the side wall 102, of the vacuum chamber 101. For example, the alignment system 130 may extend through the side wall of the vacuum chamber 101 and may be flexibly connected to the side wall, e.g. via at least one vibration isolation element. The term “flexibly connected” as used herein relates to a connection between the alignment system 130 and the side wall 102 of the vacuum chamber 101 which allows for a relative movement, e.g. a deformation or a vibration, between the side wall 102 and the alignment system 130. In other words, the alignment system 130 is movably mounted with respect to the side wall 102 such that vibrations and other deformations or movements of the side wall are not transferred from the side wall to the alignment system. This is in contrast to conventional bellow-sealed motion feedthroughs which allow for a movement of a positioner in a vacuum chamber while having the driving unit of the positioner immovably fixed at a respective side wall of the vacuum chamber. Accordingly, conventional motion feedthroughs are rigidly fixed to the side wall of the vacuum chamber through which they extend and there is no vibration damping with respect to the side wall.

The vibration damping element 103 may seal the opening in the side wall 102 of the vacuum chamber through which the alignment system 130 extends in a vacuum-tight manner.

The vibration damping element 103 or vibration isolation element may include at least one flexible or elastic element, particularly at least one expandable element, e.g. an axially expandable element such as a bellow element. For example, the vibration damping element 103 may include an elastic and vacuum-tight sealing acting between the side wall 102 of the vacuum chamber and the alignment system 130. In some embodiments, the longitudinal axis of the axially expandable element may extend in the second direction Z. For example, an elastic and/or expandable element such as a bellow element may connect the alignment system 130 with the side wall 102 of the vacuum chamber such that an opening in the side wall 102 through which the alignment system 130 extends is closed in a vacuum-tight manner. Accordingly, vibrations and other deformations of the side wall 102 do not directly transfer to the alignment system 130 because the vibration isolation element allows for a relative movement between the side wall 102 and the alignment system 130. In particular, the (stationary) main body 131 of the alignment system 130 extends through the side wall and is movably mounted with respect to the side wall via the vibration damping element 103.

The side wall 102 of the vacuum chamber 101 through which the alignment system 130 extends may be an essentially vertically extending outer side wall of the vacuum chamber. A side wall 102 of the vacuum chamber is typically less stable than the top wall which can be enforced by stabilizing elements such as reinforcing beams. Accordingly, the side wall 102 may at least in sections move or vibrate, e.g. when the pressure inside the vacuum chamber changes. Accordingly, it is beneficial to mechanically isolate the alignment system 130 from the side wall 102, such that movements of the side wall are not (directly) transferred on the alignment system.

The alignment system 130 may be rigidly fixed to the support 110 which is not fixed to the side wall 102 through which the alignment system 130 extends. In particular, the support 110 may be fixed to the top wall of the vacuum chamber and may be arranged above a carrier transportation path along which the first carrier 10 can be contactlessly transported by the magnetic levitation system 120. Accordingly, the alignment accuracy can be improved, and the position of the alignment system 130 can be maintained even if the side wall 102 moves during a pressure change inside the vacuum chamber.

In some embodiments, at least one further flexible element 104, e.g. an axially expandable element such as a bellow element, may flexibly connect the main body 131 of the alignment system 130 with the driven part 143 of the first shifting device 141. The further flexible element 104 may allow a movement of the driven part 143 in the second direction Z inside the vacuum chamber 101 while the driving unit 142 can be placed outside the vacuum chamber 101. For example, the driving unit 142 can be rigidly fixed to the main body 131 of the alignment system 130 outside the vacuum chamber. The further flexible element 104 may separate a vacuum environment which surrounds the further flexible element 104 from an atmospheric environment inside the further flexible element 104. A movable shaft or arm of the driven part 143 may axially extend through the further flexible element 104.

According to embodiments described herein, the first mount 152 can be moved together with the alignment device 151 in the second direction Z by the first shifting device 141. In particular, the first mount 152 can be moved by the first shifting device 141 toward the first carrier 10 until the first mount 152 comes in contact with and attaches to the first carrier 10. The first mount with the first carrier mounted thereon can then be moved by the first shifting device 141 in the second direction Z toward a deposition source 105 or toward a second carrier. Thereafter, a fine alignment of the first carrier via the alignment device 151 may follow.

The driving unit 142 (e.g. provided as a linear Z-actuator) of the first shifting device 141 may be arranged outside the vacuum chamber 101. A front part of the driven part 143 of the first shifting device 141 which carries the alignment device 151 and the first mount 152 may be arranged inside the vacuum chamber. Movements of the side wall 102 of the vacuum chamber 101 through which the driven part 143 extends are not transferred to the alignment system 130 because the alignment system 130 is connected to the side wall only via the at least one vibration damping element. An accurate and reproducible alignment of the first carrier can be provided, even if the pressure in the vacuum chamber varies or if the vacuum chamber is flooded and/or evacuated.

In embodiments, which can be combined with other embodiments described herein, the support 110 is configured as a guiding rail or a support girder which is provided at a top wall of the vacuum chamber 101. The alignment system 130 which is fixed to the support 110 may extend through a side wall 102 of the vacuum chamber. The top wall may be an upper, essentially horizontally extending outer wall of the vacuum chamber, and/or the side wall may extend essentially perpendicular with respect to the top wall, particularly in an essentially vertical direction.

FIG. 2 shows a vacuum system for aligning a carrier in a vacuum chamber according to embodiments described herein. The vacuum system includes a vacuum chamber 101 having a top wall and a side wall 102, and a support 110 which is provided in the vacuum chamber at the top wall. An alignment system 130 for aligning a first carrier is fixed to the support 110. In particular, a (stationary) main body 131 of the alignment system 130 is rigidly fixed to the support 110, e.g. via a plurality of screws or bolts. The alignment system 130 includes at least one alignment unit such as an alignment device and/or a first shifting device which may be fixed to the main body 131. The alignment system 130 extends through the side wall and is flexibly connected to the side wall, particularly via a vibration damping or isolation element, such that movements of the side wall do not affect the position of the alignment system 130. The vibration damping element 103 may be an axially expandable element, particularly a bellow element. In some embodiments, the vibration damping element acts as a vacuum-tight sealing between the side wall 102 and the alignment system.

In some embodiments, a driving unit 142 of the alignment system 130 may be arranged outside the vacuum chamber, and an alignment device 151 of the alignment system 130 which can be moved by the driving unit 142 may be arranged inside the vacuum chamber. A first mount 152 of the alignment system 130 can be moved by the alignment device 151 and is configured for the attachment of the first carrier 10.

The vacuum system may be a vacuum deposition system configured to deposit one or more materials on a substrate carried by the first carrier 10. A deposition source 105, particularly a vapor source configured to evaporate an organic material, may be provided in the vacuum chamber. The deposition source 105 may be arranged such that a material can be directed from the deposition source 105 toward the first carrier that is mounted to the first mount 152 of the alignment system.

The deposition source 105 may be a movable deposition source. In particular, the deposition source 105 may be movable in the first direction X past a substrate that is carried by the first carrier. A drive may be provided for providing a translational movement of the deposition source 105 in the first direction X.

Alternatively or additionally, the deposition source may include a rotatable distribution pipe provided with vapor outlets. The distribution pipe may extend essentially in a vertical direction and may be rotatable around an essentially vertical rotation axis. The deposition material may be evaporated in a crucible of the evaporation source and may be directed toward the substrate through the vapor outlets which are provided in the distribution pipe.

In particular, the deposition source 105 may be provided as a line source extending in an essentially vertical direction. The height of the deposition source 105 in the vertical direction may be adapted to a height of the vertically oriented substrate such that the substrate can be coated by moving the deposition source 105 past the substrate in the first direction X.

In some embodiments, the magnetic levitation system 120 may be configured to transport the first carrier 10 into a deposition area in the vacuum chamber 101 in which the substrate 11 faces the deposition source 105. A coating material can be deposited on the substrate in the deposition area. After the deposition of the coating material on the substrate, the magnetic levitation system 120 may transport the first carrier 10 out of the deposition area, e.g. for unloading the coated substrate from the vacuum chamber or for depositing a further coating material on the substrate in a further deposition area.

The deposition source 105 may include a distribution pipe with a plurality of vapor openings or nozzles for directing the coating material into the deposition area. Further, the deposition source may include a crucible configured for heating and evaporating the coating material. The crucible may be connected to the distribution pipe such as to be in fluid communication with the distribution pipe.

In some embodiments, which may be combined with other embodiments described herein, the deposition source may be rotatable. For example, the deposition source may be rotatable from a first orientation in which the vapor openings of the deposition source are directed toward the deposition area to a second orientation in which the vapor openings are directed toward a second deposition area. The deposition area and the second deposition area may be located on opposite sides of the deposition source, and the deposition source may be rotatable by an angle of about 180° between the deposition area and the second deposition area.

In the exemplary embodiment of FIG. 2, the magnetic levitation system 120 includes at least one magnet unit 121 arranged above the first carrier 10 at the support 110 and configured to carry at least a part of the weight of the first carrier 10. The at least one magnet unit 121 may include an actively controlled magnet unit configured to contactlessly hold the first carrier 10 below a guiding rail section of the support 110. The magnetic levitation system 120 may further include a drive device configured to contactlessly move the first carrier 10 in the first direction X. In some embodiments, the drive device may be arranged at least partially below the first carrier 10. The drive device may include a drive such as a linear motor configured to move the first carrier by applying a magnetic force on the first carrier (not depicted).

FIG. 3 shows an apparatus 300 for carrier alignment in a vacuum chamber 101 according to embodiments described herein. The apparatus 300 is similar to the apparatus 200 depicted in FIG. 2, such that reference can be made to the above explanations, which are not repeated here.

The alignment system 130 of the apparatus 300 is fixed to the support 110. Further, the at least one magnet unit 121 of the magnetic levitation system 120 is fixed to the support 110. The support 110 may be provided at the top wall of the vacuum chamber and extend in the first direction X.

The alignment system 130 which is fixed to the support 110 may be configured to align the first carrier 10 relative to a second carrier 20. In particular, the alignment system 130 may include the first mount 152 for mounting the first carrier to the alignment system, a second mount 153 for mounting the second carrier to the alignment system, and an alignment device 151 for moving the first carrier and the second carrier relative to each other.

In some embodiments, the alignment system 130 includes the first mount 152 for mounting the first carrier 10 to the alignment system, the second mount 153 for mounting a second carrier 20 to the alignment system, the first shifting device 141 configured to move the first mount in the second direction Z, and a second shifting device 144 configured to move the second mount in the second direction Z.

The first carrier 10 is typically a substrate carrier which carries a substrate 11 to be coated, and the second carrier 20 is typically a mask carrier which carries a mask 21 to be arranged in front of the substrate 11 during deposition. The first carrier 10 and the second carrier 20 can be aligned relative to each other with the alignment system 130, such that an evaporated material can be deposited exactly in a predetermined pattern defined by the mask on the substrate.

In particular, the second carrier 20 which is mounted to the second mount 153 can be moved to a predetermined position in the second direction Z with the second shifting device 144. The first carrier 10 can be moved to a predetermined position adjacent to the second carrier 20 in the second direction Z with the first shifting device 141. The first carrier 10 can then be aligned with the alignment device 151 in the alignment direction, particularly in the second direction Z, and/or optionally in one or more further alignment directions.

In some embodiments, which may be combined with other embodiments described herein, the alignment system 130 extends through a side wall 102 of the vacuum chamber 101 and is flexibly connected to the side wall 102 via the vibration damping element 103. The vibration damping element 103 may be a flexible and/or elastic element such as a bellow element. The vibration damping element 103 prevents or reduces the transfer of deformations of the side wall 102 to the alignment system 130. Reference is made to the above explanations, which are not repeated here.

In some embodiments, the second shifting device 144 includes a second driving unit 145, e.g. a linear actuator or motor, and a second driven part 146 which can be moved by the second driving unit 145 in the second direction Z. The second mount 153 is provided at the second driven part 146 to be movable together with the second driven part 146. The second driven part 146 may include a shaft which extends into the vacuum chamber through an opening in the side wall 102.

The driving unit 142 of the first shifting device 141 and a second driving unit 145 of the second shifting device 144 may be fixed to the main body 131 of the alignment system which is fixed to the support 110. Accordingly, movements of the vacuum chamber are equally transferred to the first mount and to the second mount, such that the first carrier mounted to the first mount and the second carrier mounted to the second mount move in accordance with each other when the vacuum chamber moves or vibrates.

The second driving unit 145 may be arranged outside the vacuum chamber 101, and the second driven part 146 may extend into the vacuum chamber 101, particularly through the opening provided in the side wall 102 of the vacuum chamber. The second mount 153 is provided inside the vacuum chamber 101 at a front end of the second driven part 146. Accordingly, the second carrier 20 can be mounted to the second mount 153 which is provided inside the vacuum chamber. Further, the second carrier 20 can be moved inside the vacuum chamber 101 in the second direction Z by the second shifting device 144.

The alignment system 130 includes the main body 131 which is fixed to the support 110 inside the vacuum chamber, e.g. via a plurality of bolts or screws. The driving unit 142 of the first shifting device 141 and the second driving unit 145 of the second shifting device 144 may be fixed to the main body 131 of the alignment system 130. The main body 131 of the alignment system 130 may provide a feed-through through the side wall 102 for the driven part 143 of the first shifting device and for the second driven part 146 of the second shifting device. The main body 131 of the alignment system 130 may be flexibly connected to the side wall 102 of the vacuum chamber 101, e.g. via a vibration damping element 103.

The main body 131 of the alignment system 130 may be fixed to the support 110. The support 110 may be (directly or indirectly) fixed to a top wall of the vacuum chamber and/or may be configured as a support rail or support girder which extends in the first direction X. The top wall of the vacuum chamber is typically more strongly reinforced and less movable than the vertically extending side walls.

In some embodiments, which may be combined with other embodiments described herein, the magnetic levitation system 120 may be provided for transporting the first carrier along a first transport path in the first direction X, and a second magnetic levitation system 122 may be provided for transporting the second carrier 20 along a second transport path parallel to the first transport path in the first direction X. The magnetic levitation system 120 and/or the second magnetic levitation system 122 may be configured for a contactless carrier transport. In particular, the magnetic levitation system 120 may include the at least one magnet unit 121, particularly an actively controlled magnet unit, for contactlessly holding the first carrier 10. The second magnetic levitation system 122 may include at least one second magnet unit 123, particularly an actively controlled magnet unit, for contactlessly holding the second carrier 20. Typically, each magnetic levitation system includes a plurality of actively controlled magnet units which may be arranged along the first direction X at an essentially equal spacing at the support. In particular, the at least one magnet unit 121 and the at least one second magnet unit 123 may be fixed to the support 110.

The support may include a guiding rail section for contactlessly holding the first carrier, wherein the at least one magnet unit 121 is attached to the guiding rail section, and a second guiding rail section for contactlessly holding the second carrier, wherein the at least one second magnet unit 123 is fixed to the second guiding rail section. Since the at least one magnet unit 121 and the at least one second magnet unit 123 are attached to the same mechanical support, the first carrier and the second carrier move in correspondence with each other when the support 110 moves or vibrates. Accordingly, a relative positioning of the first carrier and the second carrier during transport with the magnetic levitation systems can be maintained.

In the schematic sectional view of FIG. 3, the first carrier 10 and the second carrier 20 are contactlessly held by actively controlled magnet units of the magnetic levitation system 120 and the second magnetic levitation system 122. The first mount 152 is provided at a distance from the first carrier 10 in the second direction Z, and the second mount 153 is provided at a distance from the second carrier 20 in the second direction Z.

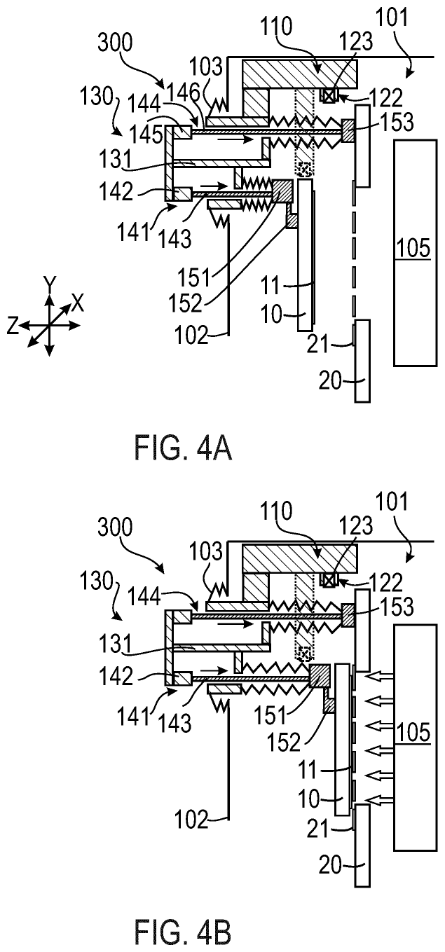

FIG. 4A shows the apparatus 300 of FIG. 3 in a second position. The second carrier 20 has been mounted to the second mount 153 by moving the second mount to the second carrier 20 in the second direction Z and magnetically attaching the second carrier 20 to the second mount 153. The second carrier 20 is then moved by the second shifting device 144 in the second direction Z to a predetermined position, e.g. by a distance of 20 mm or more. In particular, the mask 21 that is carried by the second carrier 20 is positioned at a predetermined position facing the deposition source 105.

As is further depicted in FIG. 4A, the first carrier 10 carrying the substrate 11 is transported by the magnetic levitation system 120 into the deposition area, and the first mount 152 is mounted to the first carrier by moving the first mount 152 to the first carrier 10 with the first shifting device 141.

As is schematically depicted in FIG. 4B, the first carrier 10 is then moved in the second direction Z toward the second carrier 20 by the first shifting device 141 until the substrate 11 is positioned close to the mask 21. Subsequently, the first carrier 10 is aligned in at least one alignment direction, particularly in the second direction Z, with the alignment device 151. The first carrier 10 may be positioned exactly at a predetermined position by the alignment device 151 which may include one or more piezo actuators.

One or more materials can be deposited on the substrate 11 by the deposition source 105 through the openings of the mask 21. An accurate material pattern can be deposited on the substrate.

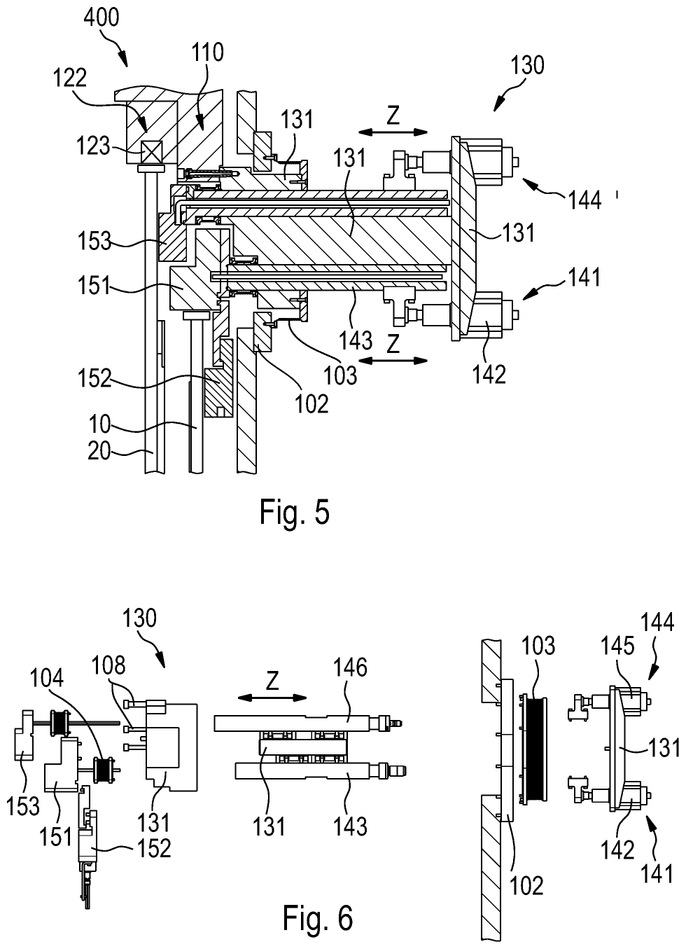

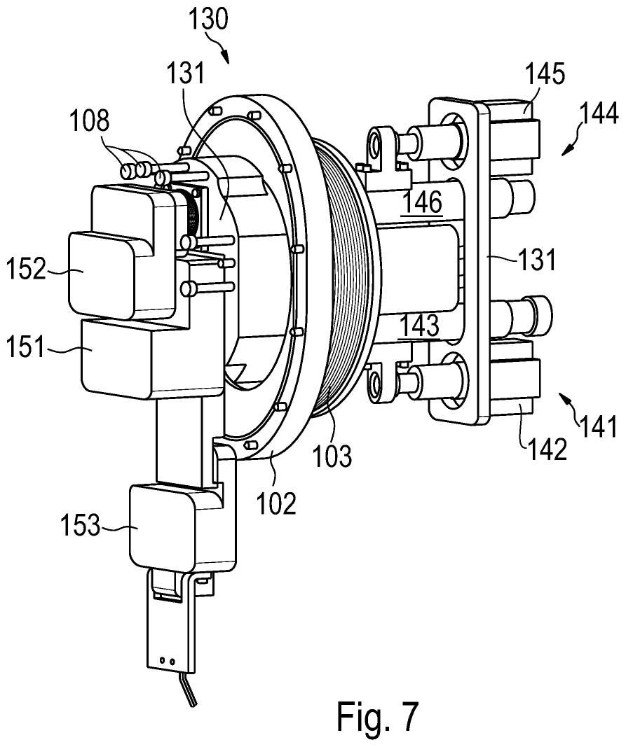

FIG. 5 is a sectional view of an apparatus 400 for aligning a carrier according to embodiments described herein. FIG. 6 is an exploded view of the alignment system 130 of the apparatus 400 of FIG. 5. FIG. 7 is a perspective view of the alignment system 130 of the apparatus 400 of FIG. 5. The apparatus 400 is similar to the apparatus 300 shown in FIG. 3, such that reference can be made to the above explanations, which are not repeated here.

The apparatus 400 includes a vacuum chamber with a side wall 102, and an alignment system 130 which extends through the side wall 102. However, the alignment system 130 is rigidly fixed to a support 110 provided at a top wall of the vacuum chamber.

Magnet units of a magnetic levitation system 120 for contactlessly transporting a first carrier 10, and magnet units of a second magnetic levitation system 122 for contactlessly transporting a second carrier 20 are provided at the support 110.

The alignment system 130 includes a main body 131 which is flexibly connected to the side wall 102 of a vacuum chamber 101 via a vibration damping element 103, e.g. via a bellow element which may at the same time act as a flexible vacuum sealing between the side wall and the alignment system. A driving unit 142 (e.g. a first Z-actuator) and a second driving unit 145 (e.g. a second Z-actuator) are fixed to the main body 131 outside the vacuum chamber 101. The main body 131 is rigidly fixed to the support 110 inside the vacuum chamber, e.g. via screws or bolts 108, and flexibly connected to the side wall 102.

The driving unit 142 is configured to move a driven part 143 which extends through the main body 131 into the vacuum chamber in the second direction Z, and the second driving unit 145 is configured to move a second driven part 146 which extends through the main body 131 into the vacuum chamber in the second direction Z. A first mount 152 for mounting a first carrier to the alignment system is provided at a front end of the driven part 143, and a second mount 153 for mounting a second carrier to the alignment system is provided at a front end of the second driven part 146. Accordingly, the first mount 152 and the second mount 153 can be moved independently of each other in the second direction Z by the respective shifting device, in order to position the first and second carriers at predetermined positions in the vacuum chamber.

The first mount 152 is connected to the driven part 143 via an alignment device 151, particularly including at least one piezo actuator. Accordingly, a fine positioning (or fine alignment) of the first carrier with respect to the second carrier can be performed by accurately positioning the first mount 152 at a predetermined position with the alignment device 151.

In some embodiments, the apparatus includes two or more alignment systems which are spaced-apart from each other in the first direction X in the deposition area. The two or more alignment systems may be fixed to the support 110. Each alignment system may be configured like the alignment system 130 according to embodiments described herein. For example, the first mount of a first alignment system may be configured to hold an upper front part of the first carrier and the first mount of a second alignment system may be configured to hold an upper rear part of the first carrier. Each alignment system may extend through the side wall 102 of the vacuum chamber. Further, each alignment system may be flexibly connected to the side wall of the vacuum system via respective vibration isolation elements. In particular, each alignment system is rigidly fixed to the support 110 that is provided inside the vacuum chamber. The support 110 may be fixed to the top wall of the vacuum chamber.

The alignment device of the first alignment system may be configured to align the first carrier in the first direction X, the second direction Z, and the third direction Y, and the alignment device of the second alignment system may be configured to align the first carrier in the first direction Z and in the third direction Y. Further alignment systems with further alignment devices may be provided. Accordingly, the first carrier, being a three-dimensional object, can be positioned and rotated exactly to a predetermined translational and rotational position in the deposition area with respect to the second carrier.

In some embodiments, further alignment systems may be provided for aligning lower parts of the first and/or second carriers. For example two further alignment systems may be provided for aligning lower front parts and a lower rear parts of the first and second carriers, e.g. in the second direction Z.

In some embodiments, which may be combined with other embodiments described herein, the driven part 143 of the first shifting device 141 is configured to feed a supply element such as a cable to a component arranged inside the vacuum chamber 101.

In particular, the driven part 143 comprises a hollow shaft configured as a cable passage for a cable extending from outside the vacuum chamber to a component arranged at a front end of the driven part 143 inside the vacuum chamber 101. For example, at least one cable connected to at least one of the alignment device 151 and the first mount 152 may extend through a hollow shaft of the driven part 143. Thus, a component which is movable in the second direction Z inside the vacuum chamber can be supplied with electrical power. For example, a piezo actuator of the alignment device 151 and/or a magnetic chuck of the first mount 152 may be supplied with electrical power from outside the vacuum chamber through the driven part 143.

In some embodiments, also the second driven part 146 of the second shifting device 144 is configured to feed a supply element such as a cable to a component arranged inside the vacuum chamber, e.g. to a component provided at a front end of the second driven part 146 inside the vacuum chamber. For example, the second mount 153 can be supplied with electrical power from outside the vacuum chamber through the driven part 146.

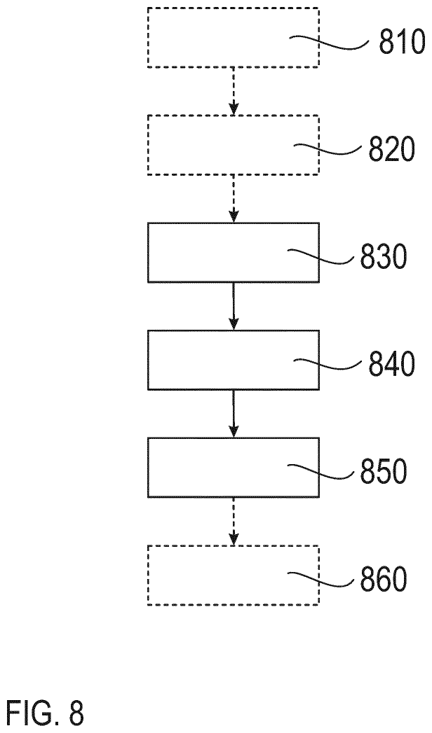

FIG. 8 is a flow diagram illustrating a method of aligning a first carrier in a vacuum chamber according to embodiments described herein.

In box 830, a first carrier which may carry a substrate to be coated is contactlessly transported along a first transport path in a first direction X in a vacuum chamber 101. The carrier is transported along a support 110 which extends in the first direction and supports at least one magnet unit 121 of a magnetic levitation system 120. The first carrier may be transported into a deposition area where a deposition source 105 and an alignment system 130 are arranged. In some embodiments, a plurality of actively controlled magnet units may be fixed to the support 110 at predetermined distances from each other in the first direction X.

In box 840, the first carrier is mounted to a first mount of the alignment system 130 that is fixed to the support 110. The first mount may be a magnetic mount configured to hold the first carrier by magnetic attraction forces.

In box 850, the first carrier is aligned in a second direction Z transverse to the first direction with the alignment system 130, and optionally in the first direction X and in the third direction Y. The alignment system 130 is fixed to the support 110.

In some embodiments, the alignment system 130 includes an alignment device configured to move the first mount in at least one alignment direction, and a first shifting device configured to move the alignment device together with the first mount in the second direction Z.

Aligning the first carrier in box 850 may include moving the first carrier (together with the alignment device) in the second direction with the first shifting device, particularly toward a previously positioned mask that is carried by a second carrier, and aligning the first carrier in at least one alignment direction with the alignment device of the alignment system. The alignment device may be provided at a driven part of the first shifting device. In particular, the substrate that is carried by the first carrier 10 is moved into contact with a mask that is carried by a second carrier.

In optional box 860, a material is deposited on the substrate that is carried by the first carrier. In particular, an evaporated organic material is deposited on the substrate by a vapor source which may be movable past the substrate.

In embodiments, which can be combined with other embodiments described herein, the first carrier is a substrate carrier carrying a substrate, and aligning the first carrier includes aligning the first carrier with respect to a second carrier mounted to a second mount of the alignment system. In particular, the second carrier is a mask carrier carrying a mask.

In optional box 810, a second carrier 20 carrying a mask 21 is transported along a second transport path which extends parallel to the first transport path in the first direction X into the deposition area. The second carrier 20 may be contactlessly transported with a second magnetic levitation system including a plurality of actively controlled magnet units which are fixed to the support 110.

In optional box 820, the second carrier 20 is mounted to a second mount of the alignment system 130, and the second carrier is moved in the second direction Z by a second shifting device of the alignment system 130, particularly toward the deposition source. The method may then proceed with box 830.

The apparatus described herein can be configured for evaporation of e.g. an organic material for the manufacture of OLED devices. For example, the deposition source can be an evaporation source, particularly an evaporation source for depositing one or more organic materials on a substrate to form a layer of an OLED device.

The embodiments described herein can be utilized for evaporation on large area substrates, e.g., for OLED display manufacturing. Specifically, the substrates for which the structures and methods according to embodiments described herein are provided, are large area substrates, e.g. having a surface area of 0.5 m² or more, particularly 1 m² or more. For instance, a large area substrate or carrier can be GEN 4.5, which corresponds to a surface area of about 0.67 m² (0.73×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

According to some embodiments, which can be combined with other embodiments described herein, the substrate thickness can be from 0.1 to 1.8 mm. The substrate thickness can be about 0.9 mm or below, such as 0.5 mm. The term “substrate” as used herein may particularly embrace substantially inflexible substrates, e.g., a wafer, slices of transparent crystal such as sapphire or the like, or a glass plate. However, the present disclosure is not limited thereto, and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

In embodiments, the first carrier 10 has a length of 1 m or more and a height of 1 m or more and is configured to carry a large-area substrate having a size of 1 m² or more, particularly 2 m² or more or 3 m² or more.

According to embodiments described herein, the substrate may be made of any material suitable for material deposition. For instance, the substrate may be made of a material selected from the group consisting of glass (for instance soda-lime glass, borosilicate glass, and the like), metal, polymer, ceramic, compound materials, carbon fiber materials or any other material or combination of materials which can be coated by a deposition process.

According to embodiments described herein, the method for transporting and aligning a substrate carrier and a mask carrier in a vacuum chamber can be conducted using computer programs, software, computer software products and the interrelated controllers, which can have a CPU, a memory, a user interface, and input and output devices being in communication with the corresponding components of the apparatus.

The present disclosure provides a first carrier transport system for a first carrier and a second carrier transport system for a second carrier that may be equally sized in at least one dimension. In other words, the second carrier may fit into the first carrier transport system and the first carrier may fit into the second carrier transport system. The first carrier transport system and the second carrier transport system can be flexibly used while providing an accurate and smooth transportation of the carriers through the vacuum system. The alignment system allows for a precise alignment of the substrate with respect to the mask, or vice versa. High quality processing results, e.g. for production of high resolution OLED devices, can be achieved.

In other embodiments, the mask carriers and the substrate carriers may be differently sized. For example, the mask carriers may be larger than the substrate carriers, particularly in a vertical direction, as is schematically depicted in FIG. 3.

According to another aspect described herein, an apparatus 900 for carrier alignment in a vacuum system including a (first) magnetic levitation system for levitating a first carrier 10 and a second magnetic levitation system for levitating a second carrier 20 is provided.

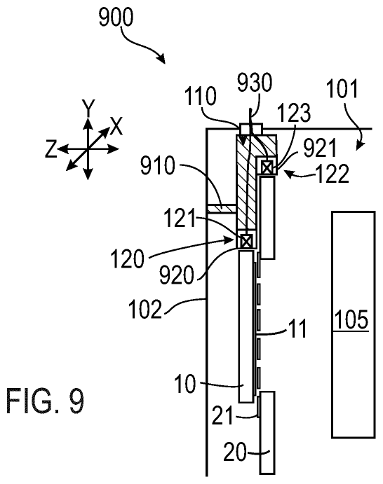

FIG. 9 is a schematic section view of the apparatus 900. The apparatus 900 includes a support 110 extending in the first direction X in the vacuum chamber 101, i.e. perpendicular to the paper plane of FIG. 9. The apparatus 900 further includes a first magnetic levitation system 120 which is configured to contactlessly transport the first carrier 10 in the first direction X along a first track, and a second magnetic levitation system 122 which is configured to contactlessly transport the second carrier 20 in the first direction X along a second track parallel to the first track. At least one first magnet unit 121 of the first magnetic levitation system 120 and at least one second magnet unit 123 of the second magnetic levitation system 122 are fixed to the support 110. The apparatus 900 may optionally further include an alignment system as described with respect to any of the embodiments herein.

In embodiments, a first plurality of active magnet units of the first magnetic levitation system may be fixed to the support 110, wherein the active magnet units of the first plurality are spaced apart from each other in the first direction X. The first plurality may include three, five, ten or more active magnet units spaced apart in the first direction X. In embodiments, a second plurality of active magnet units of the second magnetic levitation system may be fixed to the support 110 wherein the active magnet units of the second plurality are spaced apart from each other in the first direction X. The second plurality may include three, five, ten or more active magnet units spaced apart in the first direction X.

The first carrier 10 and the second carrier 20 can be contactlessly transported along the first track and the second track, respectively, at a mutual distance of 50 cm or less, particularly of 30 cm or less, more particularly of 15 cm or less. After the transport of the first carrier 10 and the second carrier 20 into a processing module where the alignment system 130 is arranged (see FIG. 3), the first carrier 10 and the second carrier 20 can be aligned relative to each other, as described herein.

The at least one first magnet unit 121 of the first magnetic levitation system 120 may be provided at a first track section of the support 110 and be configured as an actively controllable magnet unit for contactlessly holding the first carrier 10 below the first track section. The at least one second magnet unit 123 of the second magnetic levitation system 122 may be provided at a second track section of the support 110 and be configured as an actively controllable magnet unit for contactlessly holding the second carrier 20 below the second track section.

Accordingly, the magnet units of the first magnetic levitation system 120 and of the second magnetic levitation system 122 are provided at the same mechanical support which extends in the first direction X, i.e. in the transport direction of the first carrier and the second carrier. Thus, the tolerance chain can be reduced since the magnetic levitation units of both magnetic levitation systems are connected to the wall of the vacuum chamber 101 via the same mechanical support, i.e. via the support 110. Vibrations or other deformations of the vacuum chamber 101 are equally transferred to the at least one magnet unit 121 and the at least one second magnet unit 123 since these magnet units are connected to the vacuum chamber via the support 110. The alignment and positioning accuracy of the first carrier relative to the second carrier can be improved.

It is noted that also the alignment system 130 for aligning the first carrier 10 relative to the second carrier 20 as described herein may be fixed to the support 110 (see FIG. 3). Reference is made to the above explanations which are not repeated here. Accordingly, the alignment system as well as the active magnet units of two magnetic levitation systems may be provided at a common support, such that the tolerance chain can be reduced and the alignment accuracy can be increased.

The support 110 may be fixed to the top wall of the vacuum chamber and extend along the top wall in the first direction X. Typically, the top wall of a vacuum chamber is more strongly reinforced than the vertically extending side walls, such that the top wall deforms less than the other side walls upon evacuation. However, as is depicted in FIG. 9, a side fixation 910 may optionally be provided which connects the support 110 to a side wall 102 of the vacuum chamber 101, wherein the side wall 102 may extend essentially vertically. The side fixation 910 may extend in an essentially horizontal direction from the side wall 102 to a lower portion of the support 110.

In embodiments, the side fixation 910 may be provided as a strut or bar element extending in the second direction Z from the side wall 102 to the support 110. The side fixation may optionally be provided with a damping element configured to dampen movements, deformations and/or vibrations. Accordingly, the transfer of deformations of the side wall to the girder may be reduced or prevented. In some embodiments, the side fixation may be provided without a damper, i.e. as a stiff or rigid element. In some embodiments, the side fixation may be adjustable, e.g. in the second direction Z. Accordingly, a distance between the side wall and the girder may be adjusted, e.g. after a deformation of the chamber wall in the second direction Z.

In some embodiments, the at least one magnet unit 121 may be provided at a first levitation box 920 which is attached to a first track section of the support 110, and the at least one second magnet 123 may be provided at a second levitation box 921 which is attached to a second track section of the support 110. Optionally, supply cables 930, e.g. a power cable or a signal cable, of the at least one magnet unit 121 may extend from the first levitation box 920 through an inner volume of the support 110 and via a supply passage through the top wall of the vacuum chamber 101. Similarly, supply cables of the at least one second magnet unit 123 may extend from the second levitation box 921 through the inner volume of the support 110 and via the supply passage or a second supply passage through the top wall of the vacuum chamber 101.

The first track section of the support 110 may be provided at a height different from the second track section of the support 110, such that the first carrier 10 having a first vertical dimension can be levitated next to a second carrier having a second vertical dimension different from the first vertical dimension. The alignment process can be facilitated when the first carrier 10 and the second carrier 20 do not have the same vertical dimension. However, in other embodiments, the first track section and the second track section of the support may be provided essentially at the same height and be configured to transport two carriers having the same vertical dimension.

The support 110 may be configured as a support rail or support girder which may be fixed directly or indirectly to the top wall of the vacuum chamber. Reference is made to the above explanations, which are not repeated here. The apparatus 900 may be a part of a vacuum system as described herein including a vacuum chamber 101 having a top wall and a side wall 102. The support 110 is typically provided at the top wall, and an (optional) alignment system may extend through the side wall and may be flexibly connected to the side wall.

While the foregoing is directed to embodiments of the disclosure, other and further embodiments of the disclosure may be devised without departing from the basic scope thereof, and the scope thereof is determined by the claims that follow.

1. An apparatus for carrier alignment in a vacuum chamber, comprising:
a support extending in a first direction in the vacuum chamber;
a magnetic levitation system configured to transport a first carrier in the first direction in the vacuum chamber, the magnetic levitation system comprising at least one magnet unit; and
an alignment system for aligning the first carrier,
wherein the at least one magnet unit and the alignment system are fixed to the support.

2. The apparatus according to claim 1, wherein the alignment system comprises:
a first mount for mounting the first carrier to the alignment system; and
a first shifting device configured to move the first mount in a second direction transverse to the first direction.

3. The apparatus according to claim 2, wherein a driving unit of the first shifting device is fixed to a main body of the alignment system which is fixed to the support, the first mount being provided at a driven part of the first shifting device.

4. The apparatus according to claim 3, wherein the driving unit is arranged outside the vacuum chamber, and the driven part extends into the vacuum chamber through a side wall of the vacuum chamber.

5. The apparatus according to claim 2, wherein the alignment system (130) further comprises:
an alignment device, particularly a piezo actuator, configured to move the first mount in at least one alignment direction, the first shifting device being configured to move the alignment device together with the first mount in the second direction.

6. The apparatus according to claim 1, wherein the alignment system extends through a side wall of the vacuum chamber and is flexibly connected to the side wall via at least one vibration damping element, particularly via an elastic sealing such as a bellow element.

7. The apparatus according to claim 1, wherein the support is configured as a support rail or a support girder fixed to a top wall of the vacuum chamber.

8. The apparatus according to claim 1, further comprising a second magnetic levitation system configured to transport a second carrier along the first direction parallel to the first carrier, the second magnetic levitation system comprising at least one second magnet unit fixed to the support.

9. The apparatus according to claim 2, wherein the alignment system further comprises:
a second mount for mounting a second carrier to the alignment system; and
a second shifting device configured to move the second mount in the second direction.

10. The apparatus according to claim 9, wherein a driving unit of the first shifting device and a second driving unit of the second shifting device are fixed to a main body of the alignment system which is fixed to the support.

11. The apparatus according to claim 1, further comprising a second alignment system spaced-apart from the first alignment system in the first direction and fixed to the support.

12. The apparatus according to claim 1, wherein the alignment system comprises at least one alignment device, for aligning the first carrier in a second direction transverse to the first direction.

13. A vacuum system, comprising:
a vacuum chamber having a top wall and a side wall; and
an apparatus according to claim 1, wherein the support is provided at the top wall, and the alignment system extends through the side wall and is flexibly connected to the side wall.

14. An apparatus for carrier alignment in a vacuum chamber, comprising:
a support extending in a first direction in the vacuum chamber,
a magnetic levitation system configured to transport a first carrier in the first direction in the vacuum chamber, the magnetic levitation system comprising at least one magnet unit; and
a second magnetic levitation system configured to transport a second carrier in the first direction parallel to the first carrier, the second magnetic levitation system comprising at least one second magnet unit, wherein the at least one magnet unit and the at least one second magnet unit are fixed to the support.

15. A method of aligning a carrier in a vacuum chamber, comprising:
contactlessly transporting a first carrier in a first direction along a support with a magnetic levitation system, the support extending in the first direction and having at least one magnet unit of the magnetic levitation system fixed thereon, aligning the first carrier in a second direction transverse to the first direction, and optionally in the first direction and/or in a third direction transverse to the first and second directions, with an alignment system that is fixed to the support.

16. The method of claim 15, wherein aligning comprises:
mounting the first carrier to a first mount of the alignment system, moving the mount in the second direction with a first shifting device of the alignment system; and
aligning the first carrier with an alignment device provided at a driven part of the first shifting device.

17. The method of claim 15, wherein the first carrier is a substrate carrier carrying a substrate, and aligning the first carrier comprises aligning the first carrier with respect to a second carrier.

18. The apparatus according to claim 1, wherein the alignment system comprises at least one alignment device for aligning the first carrier in a second direction transverse to the first direction and in at least one of the first direction and a third direction transverse to the first and second directions.

19. The apparatus according to claim 12, wherein the at least one alignment device is a piezo actuator.

20. The apparatus according to claim 1, wherein the alignment system extends through a side wall of the vacuum chamber and is connected to the side wall via an elastic sealing such as a bellow element.
